(19) United States
(12) Patent Application Publication
(10) Pub. No.: US 2026/0231439 A1
(43) Pub. Date: Aug. 6, 2026

(54) THROUGH MOLD VIAS FOR HIGH-BANDWIDTH MEMORY DEVICES AND RELATED SYSTEMS AND METHODS

(71) Applicant: Micron Technology, Inc., Boise, ID (US)

(72) Inventors: Sujeet Ayyapureddi, Boise, ID (US); Joon Sik Sohn Lee, Meridian, ID (US)

(21) Appl. No.: 19/418,865

(22) Filed: Dec. 12, 2025

Related U.S. Application Data
(60) Provisional application No. 63/755,156, filed on Feb. 6, 2025.

(51) Int. Cl. H10B 80/00; H10W 90/00; H10W 90/20

(52) U.S. Cl. CPC H10B 80/00; H10W 90/288; H10W 90/291; H10W 90/297; H10W 90/722; H10W 90/724

(57) ABSTRACT

System-in-package devices, high-bandwidth memory devices, and associated systems and methods are disclosed herein. More specifically, a high-bandwidth memory (HBM) device according to the present technology can include a base die, a plurality of memory dies integrated with the base die, a mold compound carried by the base die surrounding the memory dies, and one or more through mold vias (TMVs) formed in the mold compound. Each of the TMVs can extend from a top surface of the mold compound to a metal layer of the base die that is thermally coupled to and/or integrally part of a physical layer interface of the base die. As a result, the TMVs can provide a thermal pathway away from the PHY through the mold compound, peripheral to the memory dies.

### CROSS-REFERENCE TO RELATED APPLICATION(S

The present application claims priority to U.S. Provisional Patent Application No. 63/755,156, filed February 6, 2025, the disclosure of which is incorporated herein by reference in its entirety.

### TECHNICAL FIELD

The present technology is generally directed to heat management in vertically stacked semiconductor devices and more specifically to through mold vias for thermal management in high-bandwidth memory devices.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet the market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet the market demands, such as by reducing the overall device footprint, can often introduce challenges in other aspects, such as maintaining circuit robustness and/or addressing increases in operating temperatures with increasing density.

### BRIEF DESCRIPTION OF THE DRAWINGS

FIG. 1 is a schematic diagram illustrating an environment that incorporates a high-bandwidth memory architecture.

FIG. 2 is a partially schematic cross-sectional diagram of a system-in-package with a high-bandwidth memory device.

FIG. 3 is a partially schematic cross-sectional diagram of a high-bandwidth memory device configured in accordance with embodiments of the present technology.

FIG. 4 is a partially schematic cross-sectional diagram of a high-bandwidth memory device configured in accordance with further embodiments of the present technology.

FIG. 5 is a flow diagram of a process for manufacturing high-bandwidth memory devices in accordance with embodiments of the present technology.

FIGS. 6A-6E are partially schematic cross-sectional diagrams of a process for manufacturing high-bandwidth memory devices in accordance with embodiments of the present technology.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

System-in-package (SiP) devices and high-bandwidth memory (HBM) devices that include features to help manage heat, and associated systems and methods, are disclosed herein. For example, as discussed in more detail below, an HBM device according to the present disclosure can include a base die, a stack of memory dies integrated with the base die, a mold compound surrounding the stack of memory dies, and a plurality of through mold vias (TMVs) formed in the mold compound. The TMVs can be thermally coupled to a physical layer (PHY) interface of the base die (referred to herein as a “PHY” for short) to provide a thermal pathway away from the PHY in the base die through the mold compound (e.g., outside of the stack of memory dies). For example, each of the TMVs can include a thermally conductive material that extends from an upper surface of the mold compound to a metal layer of the base die (e.g., at or beneath an upper surface of the base die). The metal layer, in turn, can be thermally coupled to and/or an integral part of the PHY. As a result, the heat from the PHY can be transported through the metal layer into the TMVs, and then through the TMVs to the upper surface of the mold compound, thereby defining a thermal path external to the stack of memory dies.

Although the systems and methods discussed herein are discussed primarily with reference to mitigating heat in an HBM device separate from the processing unit (e.g., a “2.5D HBM device”), one of skill in the art will understand that the processes of the present technology discussed herein are not so limited. Purely by way of example, the TMVs disclosed herein can be implemented in a 3D HBM device (e.g., memory dies stacked directly on the processing unit) to help transport heat away from the processing unit peripheral to the memory dies. Additionally, or alternatively, one of skill in the art will understand that the TMVs (and associated processes) can be deployed in various other semiconductor settings to help transport heat away from hot circuits peripheral to other dies and/or circuits.

As used herein, the terms “vertical,” “lateral,” “upper,” “lower,” “top,” and “bottom” can refer to relative directions or positions of features in the HBM devices (and SiP devices more generally) in view of the orientation shown in the drawings. For example, “bottom” can refer to a feature positioned closer to the bottom of a page than another feature. These terms, however, should be construed broadly to include HBM devices (and SiP devices) having other orientations, such as inverted or inclined orientations where top/bottom, over/under, above/below, up/down, and left/right can be interchanged depending on the orientation.

The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

Further, unless the context indicates otherwise, structures disclosed herein can be formed using one or more semiconductor manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques.

High data reliability, high speed of memory access, lower power consumption, and reduced chip size are features that are demanded from semiconductor memory. In recent years, stacked memory devices (e.g., three-dimensional (3D) memory devices) have been introduced. Some stacked memory devices are formed by stacking memory dies vertically on a base die (e.g., a “2.5D memory device”), and interconnecting the dies using through-silicon (or through-substrate) vias (TSVs). Some stacked memory devices are formed by stacking memory dies vertically directly on a processing unit (e.g., “3D memory device”) and interconnecting the dies using TSVs. Benefits of the stacked memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5D and 3D memory devices contribute to higher memory access speed, lower power consumption, and chip size reduction. Examples of stacked memory devices include Hybrid Memory Cube (HMC) and High-Bandwidth Memory (HBM). For example, HBM is a type of memory that includes a vertical stack of dynamic random-access memory (DRAM) dies and an interface die (which, e.g., provides the interface between the DRAM dies of the HBM device and a host device).

In a SiP device configuration, HBM devices may be integrated with a host device (e.g., a graphics processing unit (GPU), computer processing unit (CPU), and/or another suitable processing unit) using a base substrate (e.g., a silicon interposer, a substrate of organic material, a substrate of inorganic material and/or any other suitable material that provides interconnection between CPU/GPU and the HBM device and/or provides mechanical support for the components of a SiP device), through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device (and the silicon interposer integrating HBM devices and a host device) enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., CPU/GPU) and HBM devices during operation. For example, the high-bandwidth channels can be on the order of 1000s of gigabytes per second (GB/s, sometimes also referred to as gigabits (Gb)). It will be appreciated that such high-bandwidth data transfer between a CPU/GPU and the memory of HBM devices can be advantageous in various high-performance computing applications, such as video rendering, high-resolution graphics applications, artificial intelligence and/or machine learning (AI/ML) computing systems and other complex computational systems, autonomous control of vehicles, and/or various other computing applications.

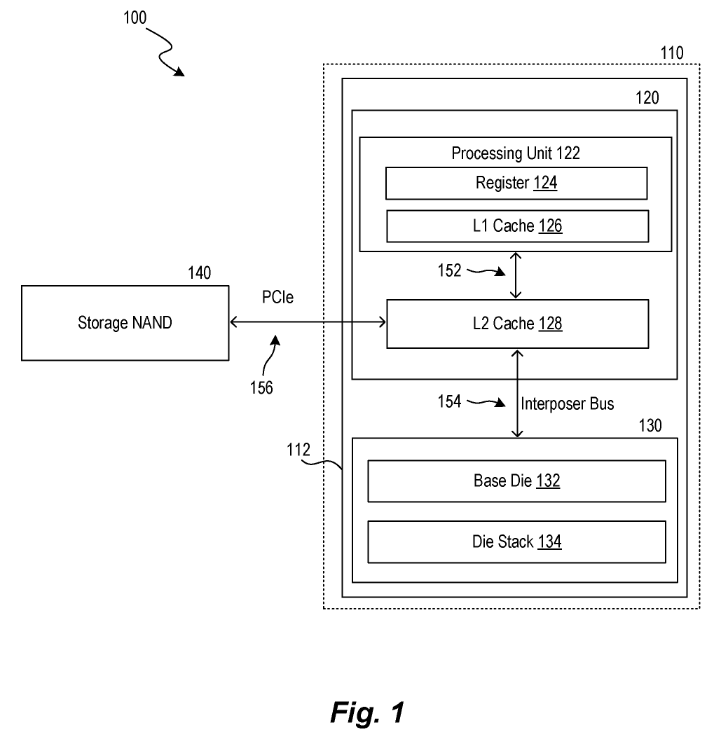

FIG. 1 is a schematic diagram illustrating an environment 100 that incorporates a high-bandwidth memory architecture. As illustrated in FIG. 1, the environment 100 includes a SiP device 110 having one or more processing devices 120 (one illustrated in FIG. 1, sometimes also referred to herein as one or more “hosts”), and one or more HBM devices 130 (one illustrated in FIG. 1), integrated with a silicon interposer 112 (or any other suitable base substrate). The environment 100 additionally includes a storage device 140 coupled to the SiP device 110. The processing device(s) 120 can include one or more processing units 122 (e.g., one or more CPUs, one or more GPUs, and/or the like), each of which may include a register 124 and a first level of cache 126. The first level of cache 126 (also referred to herein as “L1 cache”) is communicatively coupled to a second level of cache 128 (also referred to herein as “L2 cache”) via a first communication path 152. In the illustrated embodiment, the L2 cache 128 is incorporated into the processing device(s) 120. However, it will be understood that the L2 cache 128 can be integrated into the SiP device 110 separate from the processing device(s) 120. Purely by way of example, the processing device(s) 120 can be carried by a base substrate (e.g., an interposer that is itself carried by a package substrate) adjacent to the L2 cache 128 and in communication with the L2 cache 128 via one or more signal lines (or other suitable signal route lines) therein. The L2 cache 128 may be shared by one or more of the processing devices 120 (and the processing units 122 therein). During operation of the SiP device 110, the processing units 122 can use the register 124 and the L1 cache 126 to complete processing operations, and attempt to retrieve data from the larger L2 cache 128 whenever a cache miss occurs in the L1 cache 126. As a result, the multiple levels of cache can help accelerate the average time it takes for the processing device(s) 120 to access data, thereby accelerating the overall processing rates.

As further illustrated in FIG. 1, the L2 cache 128 is communicatively coupled to the HBM device(s) 130 through a second communication channel 154. As illustrated, the processing device(s) 120 (and L2 cache 128 therein) and HBM device(s) 130 are carried by and electrically coupled (e.g., integrated by) the silicon interposer 112. The second communication channel 154 is provided by the silicon interposer 112 (e.g., the silicon interposer includes and routes the interface signals forming the second communication channel, such as through one or more redistribution layers (RDLs)). As additionally illustrated in FIG. 1, the L2 cache 128 is also communicatively coupled to a storage device 140 through a third communication channel 156. As illustrated, the storage device 140 is outside of the SiP device 110 and utilizes signal routing components that are not contained within the silicon interposer 112 (e.g., between a packaged SiP device 110 and packaged storage device 140). For example, the third communication channel 156 may be a peripheral bus used to connect components on a motherboard or PCB, such as a Peripheral Component Interconnect Express (PCIe) bus. As a result, during the operation of the SiP device 110, the processing device(s) 120 can read data from and/or write data to the HBM device(s) 130 and/or the storage device 140, through the L2 cache 128.

In the illustrated environment 100, the HBM device(s) 130 each include a base die 132 and a die stack 134 communicably coupled to the base die 132. The base die 132 can include a PHY that is communicably coupled to the second communication channel 154. The PHY can receive signals from the processing device(s) 120 via the second communication channel 154 and route the signals to the die stack 134. The die stack 134 can include one or more memory dies (e.g., DRAM dies, other volatile memory dies, and/or the like) that are each communicably coupled to the PHY in the base die 132.

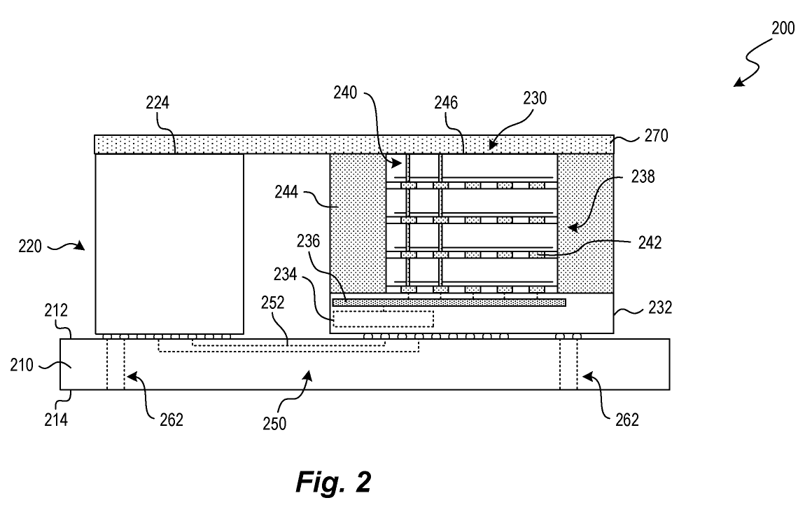

FIG. 2 is a partially schematic cross-sectional diagram of a SiP 200 that can be employed in the environment 100 discussed above with reference to FIG. 1. As illustrated in FIG. 2, the SiP 200 includes a base substrate 210 (e.g., a silicon interposer, another organic interposer, an inorganic interposer, and/or any other suitable base substrate), as well as a processing device 220 and an HBM device 230 each integrated with an upper surface 212 of the base substrate 210.

As a result, the processing device 220 can be coupled to the HBM device 230 through a high-bandwidth bus 250 that includes a substrate bus 252. For example, the processing device 220 and the HBM device 230 can each be coupled to various route lines in the substrate bus 252 via solder structures (e.g., solder balls), metal-metal bonds, and/or any other suitable conductive bonds. The route lines of the substrate bus 252, in turn, can include one or more metallization layers formed in one or more RDL layers of the base substrate 210 and/or one or more vias interconnecting the metallization layers. As a result, components of the HBM device 230 and the processing device 220 can communicate data at a relatively high rate (e.g., on the order of 1000s of GB/s).

Further, as illustrated in FIG. 2, the base substrate 210 can include one or more external TSVs 262 (four illustrated in FIG. 2) that extend from the upper surface 212 of the base substrate 210 to a lower surface 214 of the base substrate 210. The external TSVs 262 can couple the processing device 220, the HBM device 230, and/or the substrate bus 252 to package interconnects (e.g., solder structures, bond pads, and/or the like) on the lower surface. In turn, the package interconnects can be coupled to an external substrate (e.g., a package substrate), thereby communicably coupling the processing device 220, the HBM device 230, and/or the substrate bus 252 to various external components.

In the environment illustrated in FIG. 2, the processing device 220 is illustrated as a single package/component. It will be understood, however, that the processing device 220 can include a variety of components, such as a processing unit (e.g., a CPU/GPU), one or more registers, an L1 cache, an L2 cache, and/or any other suitable components. In contrast, FIG. 2 illustrates a variety of specific components of the HBM device 230. For example, the HBM device 230 includes a base die 232, one or more memory dies 238 (four illustrated in FIG. 2) integrated with the base die 232, and a mold compound 244 surrounding the memory dies 238. The base die 232 (sometimes also referred to herein as an “interface die”) includes a PHY 234 and one or more metallization layers 236 communicably coupled to the PHY 234. Each of the memory dies 238 (e.g., DRAM dies) includes a plurality of TSVs 240 and a plurality of bonding features 242 (e.g., metal-metal bonded pads, solder structures, and/or the like). The TSVs 240 and the bonding features 242 (sometimes referred to collectively as an “HBM bus”) establish a communication path between the metallization layers 236 in the base die 232 and each of the memory dies 238, thereby allowing the PHY to route signals to (and receive signals from) each of the memory dies 238. The molding compound provides physical and/or environmental protection to the base die 232 and each of the memory dies 238.

In an example of operation of the SiP 200, the processing device 220 can request information stored in the HBM device 230 through the substrate bus 252. The request is received by the PHY 234 of the base die 232. The PHY 234 then determines which of the memory dies 238 to request information from to satisfy the request from the processing device 220 (e.g., identifies which of the memory dies 238 stores the requested information). The PHY 234 then prompts the identified memory dies to forward the information via the metallization layers 236 and the HBM bus. The PHY 234 then receives the information (or an error signal) in response and forwards the information (or the error) back to the processing device 220. Operations according to the example above can share information at relatively high rates (e.g., up to an order of 1000s of GB/s), with each of the signals needing to be routed through the PHY 234. As a result, the PHY 234 can generate a substantial amount of heat. Unmitigated, the heat can elevate temperatures in the HBM device 230, thereby causing various deleterious effects in the HBM device 230, particularly within the memory dies 238. For example, the elevated temperatures can cause data loss in the memory dies 238, thereby requiring increased refresh rates to avoid errors. In turn, the increased refresh rates increase power demands for the SiP 200 and slow down processing power overall.

Accordingly, it is advantageous to dissipate the heat away from the HBM device 230 (and/or the SiP 200 more broadly) to help avoid the deleterious effects. To help dissipate the heat, as further illustrated in FIG. 2, the SiP 200 can include a thermal lid 270 that is carried by an uppermost surface 224 of the processing device 220 and a topmost surface 246 of the HBM device 230 (e.g., an upper surface of an uppermost memory die and/or an uppermost surface of the mold compound 244). During operation, heat from the PHY 234 is communicated through the memory dies 238 (e.g., via the TSVs 240) and the mold compound 244 and into the thermal lid 270. The heat is then dissipated, helping keep the base die 232 and/or each of the memory dies 238 below a threshold temperature.

As demands for the SiP 200 increase, however, the number of the memory dies 238 and/or communication routes (e.g., the number of the TSVs 240 in the HBM bus and/or the like) is increased. While the increased number of the memory dies 238 and/or the increased number of channels can help expand the overall capacity and/or the communication bandwidth within the SiP, the increases are associated with corresponding increases in the amount of heat generated in the PHY. The increases in heat generation, in turn, threaten the deleterious effects discussed above.

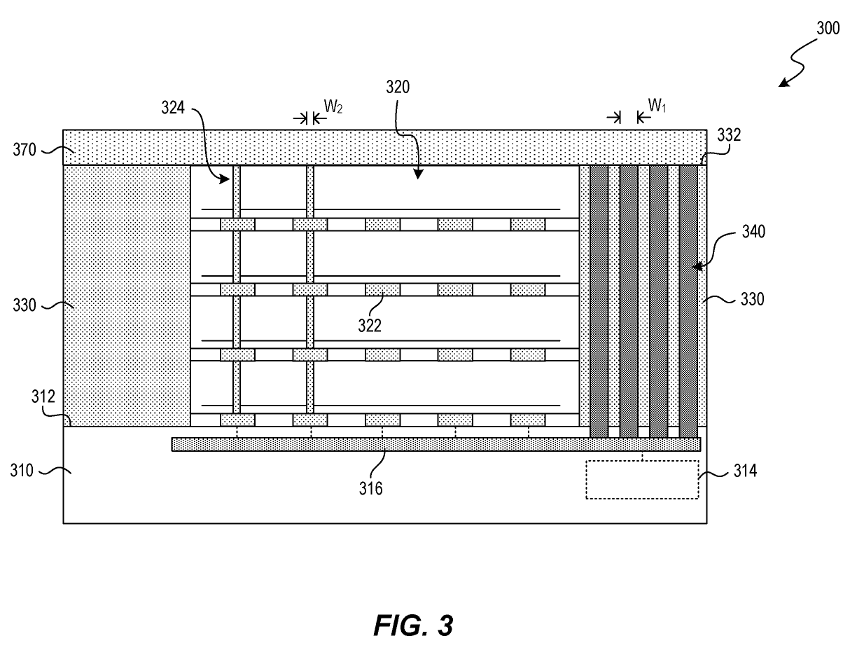

HBM devices, and associated systems and methods, for addressing the challenges posed by heat generation in the PHY are disclosed herein. For example, FIG. 3 is a partially schematic cross-sectional diagram of an HBM device 300 configured in accordance with embodiments of the present technology. As illustrated in FIG. 3, the HBM device 300 is generally similar to the HBM device 230 discussed above with reference to FIG. 2. For example, the HBM device 300 includes a base die 310, one or more memory dies 320 integrated with (e.g., carried by and electrically coupled to) an upper surface 312 of a central portion the base die 310, and a mold compound 330 deposited over the upper surface 312 surrounding the memory dies 320 (e.g., over a peripheral portion of the upper surface 312 of the base die 310). Further, the base die 310 includes a PHY 314 and one or more metallization layers 316 communicably coupled to and/or integrated with the PHY 314. Still further, the memory dies 320 (sometimes referred to collectively herein as a “memory die stack,” a “stack of memory dies,” and/or the like) includes an HBM bus communicably coupling each of the memory dies 320 to at least one of the metallization layers 316 (e.g., a redistribution layer) in the base die 310. Similar to the discussion above, the HBM bus can include a plurality of TSVs 324 and a plurality of bonding features 322 (e.g., bond sites (e.g., copper pads, gold-plated pads, exposed pads, and/or the like) bonded via metal-metal bonds, solder structures (e.g., solder balls, solder pillars, and/or the like), and/or the like) each communicably coupled between corresponding TSVs 324 and/or other suitable features in the memory dies 320.

As further illustrated in FIG. 3, however, the HBM device 300 can include one or more through mold vias (TMVs) 340 (four illustrated in FIG. 3). The TMVs 340 are positioned over the peripheral portion of the base die 310 and extend from an upper surface 332 of the mold compound 330 to the metallization layers 316 (and/or directly to the PHY 314), thereby thermally coupling the TMVs 340 to the PHY 314. As discussed in more detail below, the TMVs 340 can be manufactured by forming openings in the mold compound 330 and then filling the openings with a thermally conductive material such as copper, gold, nickel, thermal pastes, and/or the like. As a result, the TMVs 340 can provide a direct thermal pathway, through the mold compound 330, from the PHY 314 to a thermal lid 370 carried by the HBM device 300. As a result, the TMVs 340 can directly communicate heat from the PHY 314 to the thermal lid 370 without requiring heat to pass through the memory dies 320. By providing a thermal path outside of the memory dies 320, the TMVs 340 can help lower an operating temperature in the memory dies 320, which can help prevent the deleterious effects discussed above such as thermal throttling, increased refresh rates, increased power consumption, and/or the like. Additionally, or alternatively, the direct communication can increase the amount of heat that can be communicated to the thermal lid 370 outside of the memory dies 320. As a result, the TMVs 340 can help enable the PHY 314 to perform more signal routing (e.g., increase in density) without increasing the operating temperature of the memory dies 320. Additionally, or alternatively, the direct communication through the TMVs 340 can help increase a speed at which heat is communicated to the thermal lid 370, thereby helping increase the amount of heat communicated away from the PHY 314 in the base die 310. As a result, the direct communication can help reduce heat build-up within the HBM device 300, thereby further helping lower the operating temperature in the memory dies 320 and/or maintain the operating temperature with increased signal routing.

In some embodiments, the HBM device 300 is constructed to help facilitate the thermal communication through the TMVs 340. For example, the metallization layers 316 can include one or more dedicated thermal channels that are exclusively coupled between the PHY 314 and the TMVs 340 (e.g., and are not thermally and/or electrically coupled to the memory dies 320). In some such embodiments, the dedicated thermal channels are at least partially insulated from electrical channels in the metallization layers 316 coupled between the PHY 314 and the memory dies 320. In another example, as further illustrated in FIG. 3, the PHY 314 can be positioned in a peripheral portion of the base die 310 (e.g., an outer portion, a peripheral to a die-stacking portion, and/or the like) portion surrounding. As a result, the TMVs 340 can be formed in the mold compound 330 vertically aligned with a portion (or all) of the PHY 314. Additionally, or alternatively, because the memory dies 320 are positioned over a central portion (e.g., an inner region, a die-stacking region, and/or the like) of the upper surface 312, the memory dies 320 can be laterally spaced apart from (e.g., not vertically aligned) with the PHY 314. The lateral spacing can help provide thermal separation between the PHY 314 and the memory dies 320 such that heat primarily travels through the TMVs 340. As a result, the TMVs 340 provide the shortest path between the PHY 314 and the thermal lid 370 for heat to travel, which can help increase the amount of heat that is communicated through the TMVs 340 compared to through the memory dies 320. Further, in some such embodiments, the alignment (and spacing) discussed above do not require an increase in footprint for the HBM device 300 (e.g., such that the HBM device 300 of FIG. 3 has a generally equal footprint to the HBM device 230 of FIG. 2). In yet another example, as schematically illustrated in FIG. 3, the TMVs can have a first cross-sectional width W₁ (e.g., a cross-sectional diameter) that is greater or larger than a second cross-sectional width W₂ of the TSVs 324 in the memory dies 320. As a result, the TMVs 340 can provide a larger communication bandwidth for the heat, thereby further encouraging the heat to travel through the TMVs 340 rather than through the memory dies 320.

In various embodiments, the number and cross-sectional size of the TMVs 340 can vary as a trade-off between the thermal communication capacity provided by the conductive material and mechanical stabilization/physical protection provided by the mold compound 330. For example, the number and size of the TMVs 340 can be selected to increase (or maximize) a metal-density-by-volume in the mold compound 330 while maintaining the mechanical stability/physical protection provided by the mold compound 330. The increase (or maximization) of the metal-density-by-volume can help increase (or maximize) the bandwidth of the thermal communication path peripheral to the memory dies 320. In some embodiments, a footprint of the HBM device 300 is not expanded to accommodate the TMVs 340. That is, the TMVs 340 can be formed in the mold compound 330 in without modifying a width of the mold compound 330 adjacent to the memory dies 320. In some embodiments, the footprint of the HBM device 300 is increased to accommodate additional TMVs. The increase balances a tradeoff between size constraints for the HBM device 300 and functionality and/or heat mitigating requirements for the HBM device 300.

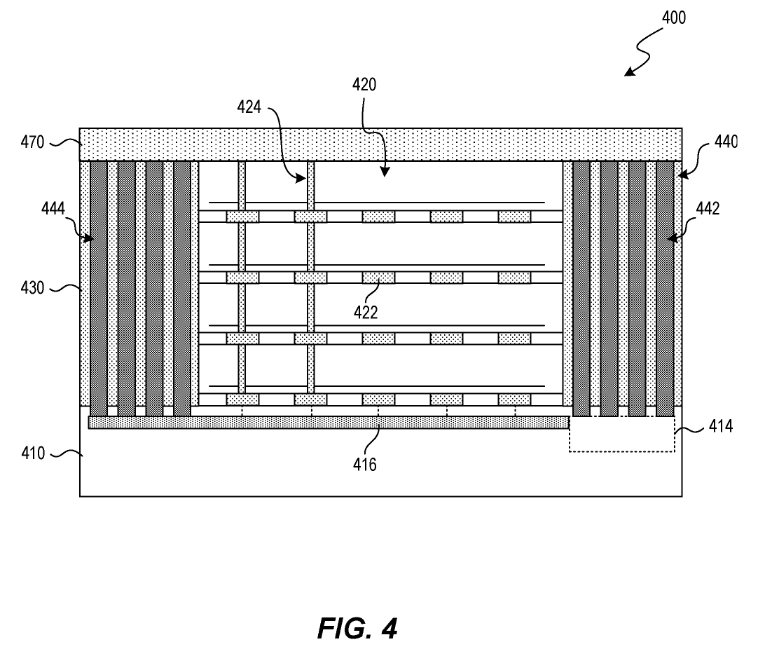

FIG. 4 is a partially schematic cross-sectional diagram of an HBM device 400 configured in accordance with further embodiments of the present technology. As illustrated in FIG. 4, the HBM device 400 is generally similar to the HBM device 300 discussed above with reference to FIG. 3. For example, the HBM device 400 of FIG. 4 includes a base die 410, a plurality of memory dies 420 integrated with the base die 410, and a mold compound 430 deposited over the base die 410 surrounding the memory dies 420. Further, the base die 410 includes a PHY 314 and one or more metallization layers 416 communicably coupled to and/or integrated with the PHY 414. Similarly, the memory dies 420 include a plurality of TSVs 424 and a plurality of bonding features 422 communicably coupling each of the memory dies 420 to at least one of the metallization layers 416.

Still further, the HBM device 400 includes a plurality of TMVs 440 formed through the mold compound 430. In the illustrated embodiments, however, the TMVs 440 are formed fully surrounding the memory dies 420 (e.g., on both lateral sides illustrated, circumferentially surrounding, and/or the like). As a result, for example, a first portion 442 of the TMVs 440 can be vertically aligned with and/or directly thermally coupled to the PHY 414 while a second portion 444 of the TMVs 440 is positioned opposite the first portion 442 and is thermally coupled to the PHY 414 via one or more of the metallization layers 416. The additional TMVs 440 in the second portion 444 can provide additional thermal pathways to a thermal lid 470 that are external to the memory dies 420. As a result, the additional TMVs 440 can further help reduce an operating temperature of the memory dies 420. Additionally, or alternatively, the additional TMVs 440 can increase the amount of heat that can be communicated to the thermal lid 470 outside of the memory dies 420 (e.g., allowing for increased signal routing within the PHY 414 without increasing the operating temperature of the memory dies 420).

Additionally, or alternatively, the symmetrical positioning of the TMVs 440 can help increase a mechanical stability of the HBM device 400. As a result, the symmetrical construction can help reduce the chance of damage during various packaging processes and/or operation of the HBM device 400. In turn, the increased mechanical stability can help extend a lifetime of the HBM device 400 and/or allow for increases in the metal-density-by-volume in the mold compound 430 without reducing the lifetime of the HBM device 400.

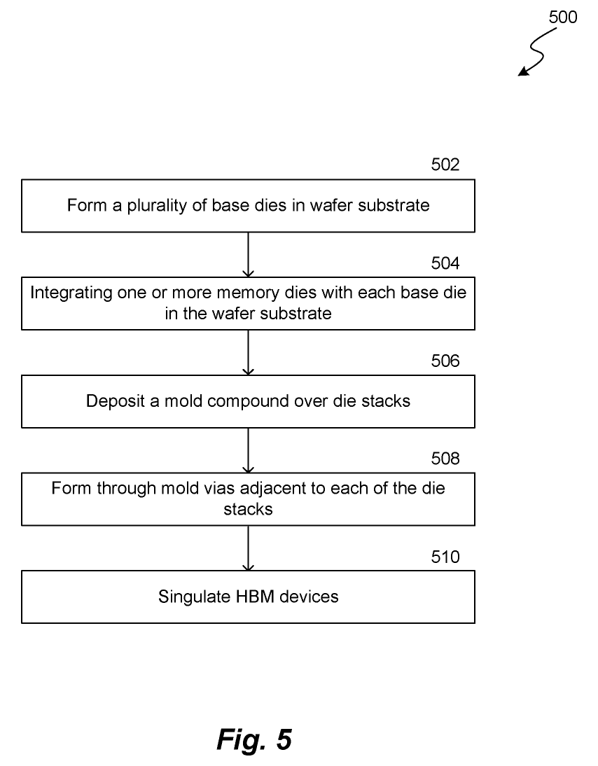

FIG. 5 is a flow diagram of a process 500 for manufacturing HBM devices in accordance with embodiments of the present technology. The process 500 can be implemented by a single manufacturing apparatus and/or split between multiple manufacturing apparatuses to construct HBM devices that include TMVs to help dissipate heat away from the base die.

The process 500 begins at block 502 forming a plurality of base dies in a wafer substrate. The process 500 at block 502 can include various front-end-of-line (FEOL) and/or back-end-of-line (BEOL) processes to form, for each of the base dies, a PHY, various other suitable circuits, one or more metallization layers (e.g., electrical routing layers, thermal routing layers, and/or the like), bond sites, package bond sites, and/or any other suitable component.

At block 504, the process 500 includes integrating one or more memory dies (e.g., DRAM dies) with each base die in the wafer substrate. Integrating the memory dies can include stacking one or more memory dies over the base die and completing a bonding process for the stacked dies. The bonding process can include forming hybrid bonds (e.g., metal-metal bonds and hybrid bonds, sometimes also referred to collectively as direct bonds) between adjacent dies, various reflow processes, and/or the like. The process 500 at block 504 can then repeat until a predetermined die stack is integrated with each of the base dies in the wafer substrate.

At block 506, the process 500 includes depositing a mold compound over the die stacks and exposed portions of the wafer substrate. The mold compound can be an epoxy-based resin and/or any other suitable material to provide mechanical stability and/or physical and environmental protection to the die stacks. Once deposited, the mold compound covers the exposed portions of each of the base dies in the wafer substrate peripheral to the die stacks and surrounds the die stacks. Further, once deposited, the mold compound has an upper surface that is coplanar with an uppermost surface of the die stacks.

At block 508, the process 500 includes forming through mold vias in the mold compound adjacent to each of the die stacks. In some embodiments, forming the through mold vias includes laser-etching (sometimes also referred to as “laser drilling”) openings in the mold compound, then depositing a conductive material (e.g., copper, gold, nickel, and/or any other suitable material) into the openings. In various embodiments, the laser-etching process can form openings extending from an upper surface of the mold compound to a lower surface of the mold compound, a metal layer within the wafer substrate (e.g., a routing layer of the base die and/or a metal layer in a PHY), and/or an intermediate depth within the wafer substrate (e.g., to an intermediate layer in the wafer substrate). In various embodiments, depositing the conductive material into the openings can include an electroplating process, a spin coating process, electroless plating, physical vapor deposition (PVD), chemical vapor deposition (CVD), and/or the like. In some embodiments, the process 500 at block 508 includes a planarization process to remove excess metal at the upper surface of the mold compound to help ensure a planar upper surface for each HBM device.

At block 510, the process 500 includes singulating the resulting HBM devices. In various embodiments, the singulation process can include stealth dicing through the wafer substrate and mold compound, mechanical dicing through the wafer substrate and mold compound, laser etching along singulation lines, and/or any other suitable singulation process.

Although blocks 502–510 are illustrated and discussed with reference to FIG. 5 in a particular order, one of skill in the art will understand that the technology disclosed herein is not so limited. Purely by way of example, the HBM devices can be singulated before forming the TMVs at a package level (e.g., by executing block 510 before block 508). The package-level formation of the TMVs can allow the process 500 to test singulated HBM devices to confirm their functionality after the singulation process before expending time and resources to form the TMVs. In a related example, wafers of memory dies can be stacked on and integrated with a base-die wafer before a singulation process to isolate the HBM devices. The isolated HBM devices can then be at least partially encased with the mold compound at the package level and the TMVs formed in the mold compound. Additionally, or alternatively, it will be understood that the process 500 can include various additional steps and/or sub-processes. Purely by way of example, the process 500 can include integrating the singulated HBM devices with a base substrate (e.g., a silicon interposer, another organic interposer, an inorganic interposer, and/or any other suitable base substrate) of a SiP device. Once integrated, a thermal lid can be stacked over the HBM device (and any adjacent devices, such as other HBM devices, a processing device, and/or the like).

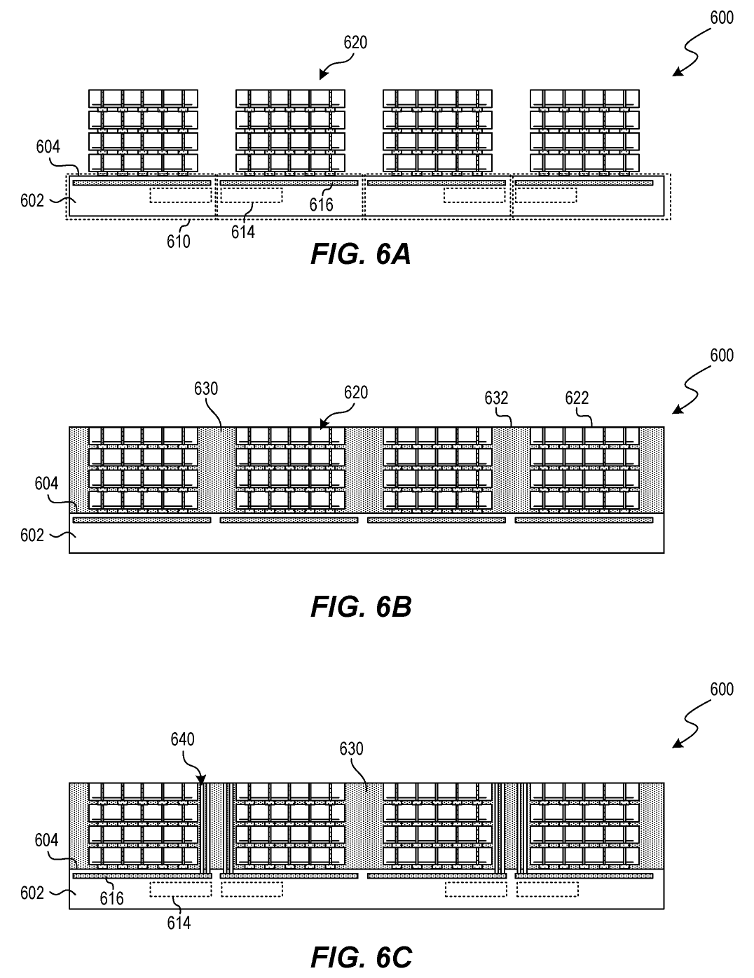

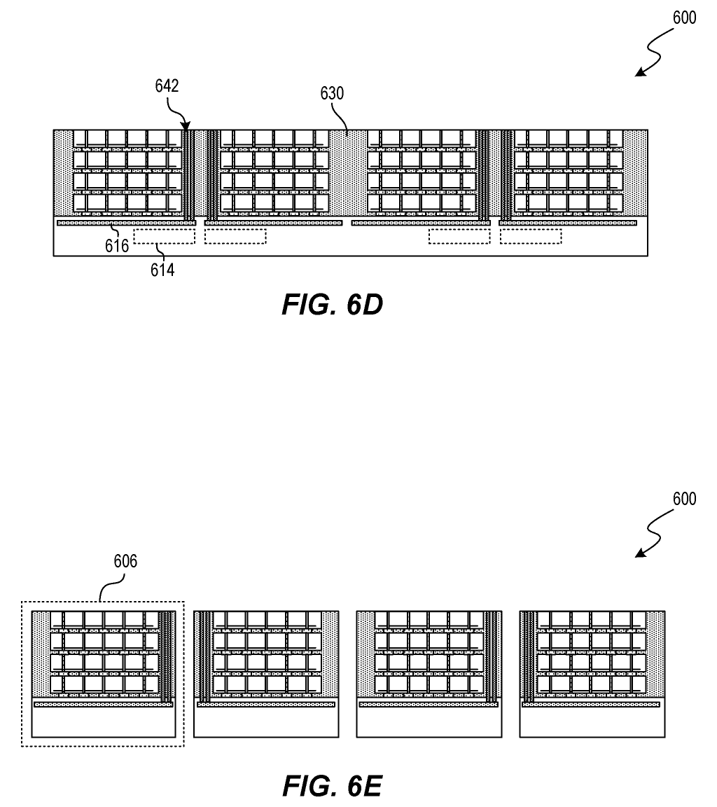

FIGS. 6A-6E are partially schematic cross-sectional diagrams of an environment 600 at various stages of a process for manufacturing HBM devices in accordance with embodiments of the present technology. The process illustrated in FIGS. 6A-6E is generally similar to the process 500 discussed above with reference to FIG. 5. Accordingly, frequent reference is made to blocks 502–510 in the discussion of the environment 600 in FIGS. 6A-6E .

For example, FIG. 6A illustrates the environment 600 after integrating, for each of a plurality of base dies 610 formed in a wafer substrate 602, one or more memory dies 620 with an upper surface 604 of the wafer substrate 602 (e.g., after block 504 of FIG. 5). In the illustrated embodiment, each of the base dies 610 includes a PHY 614 and one or more metallization layers 616 formed in the wafer substrate 602. Further, each of the memory dies 620 is communicably coupled to the PHY 614 via one or more TSVs and/or the metallization layers 616.

FIG. 6B illustrates the environment 600 after a mold compound 630 is deposited over the upper surface 604 of the wafer substrate 602 surrounding the memory dies 620 (e.g., after block 506 of FIG. 5). As illustrated in FIG. 6B, an upper surface 632 of the mold compound 630 can be coplanar with an upper surface 622 of the memory dies 620 after the deposition (and/or any planarization process), thereby providing a planar upper surface for planned HBM devices. In some embodiments, however, the upper surface 632 of the mold compound 630 is not coplanar with the upper surface 622 of the memory dies 620 until later in the process (e.g., after a planarization process on TMVs).

FIG. 6C illustrates the environment 600 after forming openings 640 through the mold compound 630 and into at least a portion of the upper surface 604 of the wafer substrate 602 (e.g., during block 508 of FIG. 5). Similar to the discussion above, the openings 640 can be formed by a laser-etching process. Further, as illustrated in FIG. 6C, the openings 640 can expose at least a portion of the metallization layers 616 and/or the PHY 614. As a result, the openings 640 provide direct access to the metallization layers 616 and/or the PHY 614 for a thermally conductive material. In the embodiments illustrated in FIG. 6C, the openings 640 are formed through the mold compound 630 vertically aligned with the PHY 614. As discussed above, the vertical alignment can allow resulting TMVs to provide the shortest thermal path between the PHY 614 and an upper surface of resulting HBM devices, thereby encouraging heat to travel through the resulting TMVs. It will be understood, however, that the technology is not so limited. For example, in some embodiments, the openings 640 are not aligned with the PHY 614 (e.g., when the PHY 614 is directly below the memory dies 620, when there is more space for TMVs in other locations, and/or the like). In another example, the openings 640 can be formed through the mold compound 630 circumferentially surrounding each of the stacks of the memory dies 620 (e.g., as discussed above with reference to FIG. 4).

FIG. 6D illustrates the environment 600 after depositing a conductive material into the openings 640 (FIG. 6C) to complete TMVs 642 through the mold compound 630 (e.g., after completing block 508 of FIG. 5). The deposition process forms a continuous conductive material (e.g., copper, gold, nickel, thermally conductive paste, and/or the like) in the openings 640 (FIG. 6C) extending from the metallization layers 616 and/or a portion of the PHY 614 to a topmost surface of the planned HBM devices. As a result, as discussed above, the TMVs 642 provide a thermal path from the PHY 614 to the topmost surface of the planned HBM devices through the mold compound 630. Similar to the discussion above, the deposition process can include an electroplating process, a spin coating process, electroless plating, physical vapor deposition (PVD), chemical vapor deposition (CVD), and/or the like. In some embodiments, the deposition process includes a planarization process to help ensure the resulting HBM devices have a planar upper surface.

FIG. 6E illustrates the environment 600 after singulating individual HBM devices 606 from each other (e.g., after block 510 of FIG. 5). As discussed above, the singulation process can include a stealth dicing process, a mechanical dicing process, a laser-etching process, a chemical singulation process, and/or any other suitable singulation process. The resulting HBM devices 606 can then be stacked on another substrate (e.g., the base substrate 210 of FIG. 2) during a manufacturing process of SiP devices.

### Conclusion

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally, “approximately,” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A high-bandwidth memory (HBM) device, comprising:
a base die;
a plurality of memory dies integrated with a central portion of an upper surface of the base die;
a mold compound carried by a peripheral portion of the upper surface of the base die; and
a plurality of through mold vias (TMVs) formed in the mold compound, wherein each of the plurality of TMVs extends from a top surface of the mold compound to a metal layer of the base die.

2. The HBM device of claim 1 wherein the plurality of memory dies comprise a plurality of through substrate vias (TSVs), wherein each of the plurality of TMVs has a larger cross-sectional area than any of the plurality of TSVs.

3. The HBM device of claim 1 wherein the metal layer of the base die is thermally coupled to a physical layer interface of the base die of the base die.

4. The HBM device of claim 1 wherein the metal layer of the base die forms a portion of a physical layer of the base die.

5. The HBM device of claim 1 wherein the metal layer of the base die is positioned beneath the upper surface of the base die.

6. The HBM device of claim 1 wherein each of the plurality of TMVs is vertically aligned with a physical layer of the base die.

7. The HBM device of claim 1 wherein the plurality of TMVs at least partially surround the plurality of memory dies.

8. The HBM device of claim 1 wherein the top surface of the mold compound is coplanar with an uppermost surface of the plurality of memory dies.

9. The HBM device of claim 1 wherein the plurality of TMVs are electrically isolated from the plurality of memory dies.

10. The HBM device of claim 1 wherein each of the plurality of TMVs comprises a thermally conductive material deposited into an opening formed through the mold compound and into at least a portion of the base die.

11. A system-in-package (SiP) device, comprising:
a base substrate;
a processing unit carried by the base substrate; and
a high-bandwidth memory (HBM) device carried by the base substrate and electrically coupled to the processing unit through one or more route lines in the base substrate, wherein the HBM device comprises:
a base die;
a stack of memory dies carried by an upper surface of the base die;
a mold compound carried by the upper surface of the base die surrounding the stack of memory dies; and
a through mold via (TMV) forming a thermal communication path through the mold compound, wherein the TMV extends from a top surface of the mold compound to a metal layer of the base die.

12. The SiP device of claim 11 wherein the mold compound thermally separates the TMV from the stack of memory dies.

13. The SiP device of claim 11, further comprising a thermal lid carried by an uppermost surface of the processing unit and a topmost surface of the HBM device, wherein the TMV is thermally coupled to the thermal lid.

14. The SiP device of claim 11 wherein the base die includes a physical layer (PHY) interface of the base die to route signals between the stack of memory dies and the processing unit, and wherein the TMV is vertically aligned with at least a portion of the PHY interface.

15. The SiP device of claim 11 wherein the base die includes a physical layer (PHY) interface of the base die to route signals between the stack of memory dies and the processing unit, and wherein the TMV is directly thermally coupled to the PHY interface.

16. The SiP device of claim 11 wherein the TMV is a first TMV positioned adjacent to a first side of the stack of memory dies, wherein the HBM device further comprises a second TMV extending from the top surface of the mold compound to the metal layer of the base die, and wherein the second TMV is positioned adjacent to a second side of the stack of memory dies opposite the first side.

17. The SiP device of claim 11 wherein the TMV comprises a continuous conductive material extending from the top surface of the mold compound to the metal layer of the base die.

18. A method of forming a high-bandwidth memory device, the method comprising:
forming a plurality of base dies in a wafer substrate;
for each of the plurality of base dies, stacking a plurality of memory dies on an upper surface of the wafer substrate to form a die stack;
depositing a mold material over the upper surface of the wafer substrate such that the mold material surrounds the plurality of memory dies in each die stack;
for each of the plurality of base dies, forming a plurality of through mold vias (TMVs) in the mold material adjacent to the die stack; and
singulating individual high-bandwidth memory (HBM) devices from the wafer substrate corresponding to each individual base die from the plurality of base dies.

19. The method of claim 18 wherein forming the plurality of TMVs comprises, for each of the plurality of TMVs:
forming an opening through the mold material; and
filling the opening with a thermally conductive material.

20. The method of claim 19 wherein, for each of the plurality of TMVs, the opening extends from a top surface of the mold material to an intermediate layer in the wafer substrate beneath the upper surface.
